(19) United States
(12) Patent Application Publication
(10) Pub. No.: US 2018/0254206 A1
(43) Pub. Date: Sep. 6, 2018

(54) ROTOR COVER

(71) Applicant: Applied Materials, Inc., Santa Clara, CA (US)

(72) Inventors: Lara Hawrylchak, Gilroy, CA (US); Chaitanya A. Prasad, Bangalore (IN); Emre Cuvalci, San Jose, CA (US)

(21) Appl. No.: 15/913,496

(22) Filed: Mar. 6, 2018

Related U.S. Application Data
(60) Provisional application No. 62/467,698, filed on Mar. 6, 2017.

(51) Int. Cl. H01L 21/67; F01L 9/04; B04B 7/04; H01L 21/02

(52) U.S. Cl. CPC H01L 21/67109; F01L 9/04; H01L 21/02312; H01L 21/67017; B04B 7/04

(57) ABSTRACT

Implementations described herein generally relate to a processing apparatus having a rotor cover for preheating the process gas. The apparatus includes a chamber body having a side wall and a bottom wall defining an interior processing region. The chamber also includes a substrate support disposed in the interior processing region of the chamber body, a ring support, and a rotor cover. The rotor cover is disposed on a ring support. The rotor cover is an opaque quartz material. The rotor cover advantageously provides for more efficient heating of process gases, is composed of a material capable of withstanding process conditions while providing for more efficient and uniform processing, and has a low CTE reducing particle contamination due to excessive expansion during processing.

### CROSS-REFERENCE TO RELATED APPLICATIONS

This application claims benefit of U.S. Provisional Patent Application Ser. No. 62/467,698 filed Mar. 6, 2017, which is incorporated herein by reference.

### BACKGROUND

### Field

Implementations described herein generally relate to thermal treatment of substrates.

### Description of the Related Art

Thermal treatment of substrates is a staple of the semiconductor manufacturing industry. Substrates are subjected to thermal treatments in a variety of processes and apparatuses. In some processes, substrates are subjected to annealing thermal energy, while others, they may also be subjected to oxidizing other reactive chemical conditions. One substrate after another is positioned in an apparatus, heated for processing, and then cooled. The apparatus for thermally processing the substrate may undergo hundreds of extreme heating and cooling cycles every day.

In addition to thermal treatment of substrates, various aspects of operating the apparatus may require materials with certain electrical, optical, or thermal properties. Adding to the complexity, continuous reduction in size of semiconductor devices is dependent upon more precise control of, for instance, the flow and temperature of process gases delivered to a semiconductor process chamber. In a cross-flow process chamber, a process gas may be delivered to the chamber and directed across the surface of a substrate to be processed. Design of an apparatus can present formidable engineering challenges to those wishing to prolong the useful life of such apparatus under the extreme conditions to which they are subjected.

Thus, there is a need for apparatus capable of performing reliably under the extreme thermal cycling of modern semiconductor processes.

### SUMMARY OF THE INVENTION

Implementations described herein generally relate to a thermal processing apparatus. In one implementation, a rotor cover for a thermal treatment chamber is disclosed. The rotor cover includes an annulus having an inner portion and an outer portion. The annulus is an opaque quartz material.

In another implementation, an apparatus for processing a substrate is disclosed. The apparatus includes a chamber body having a side wall and a bottom wall defining an interior processing region. The chamber also includes a substrate support disposed in the interior processing region of the chamber body, a ring support, and a rotor cover disposed on the ring support. The rotor cover is an opaque quartz material.

In yet another implementation, an apparatus for processing a substrate is disclosed. The apparatus includes a chamber body having a side wall and a bottom wall defining an interior processing region. The chamber also includes a substrate support disposed in the interior processing region of the chamber body, a ring support, and a rotor cover disposed on the ring support. The rotor cover includes an outer portion and an inner portion. The outer portion has a height substantially the same as the inner portion.

### BRIEF DESCRIPTION OF THE DRAWINGS

So that the manner in which the above recited features of the present invention can be understood in detail, a more particular description of the invention, briefly summarized above, may be had by reference to implementations, some of which are illustrated in the appended drawings. It is to be noted, however, that the appended drawings illustrate only typical implementations of this invention and are therefore not to be considered limiting of its scope, for the invention may admit to other equally effective implementations.

FIG. 1 shows a cross sectional view of a process chamber according to one implementation.

FIG. 2A shows a top view of the rotor cover according to one implementation described herein.

FIG. 2B shows a perspective view of a rotor cover according to one implementation described herein.

FIG. 2C shows a perspective view of a rotor cover according to another implementation described herein.

FIG. 3 shows a cross sectional view of a rotor cover according to one implementation described herein.

FIG. 4 shows a cross sectional view of a rotor cover according to one implementation described herein.

### DETAILED DESCRIPTION

Implementations described herein generally relate to a processing apparatus having a rotor cover for preheating the process gas. The rotor cover is disposed on a ring support. The rotor cover may have a segment adjacent a process gas inlet. The segment includes a top surface, and the top surface includes features to increase the surface area. The rotor cover is an opaque quartz material. The rotor cover advantageously provides for more efficient heating of process gases, is composed of a material capable of withstanding process conditions while providing for more efficient and uniform processing, and has a low CTE reducing particle contamination due to excessive expansion during processing

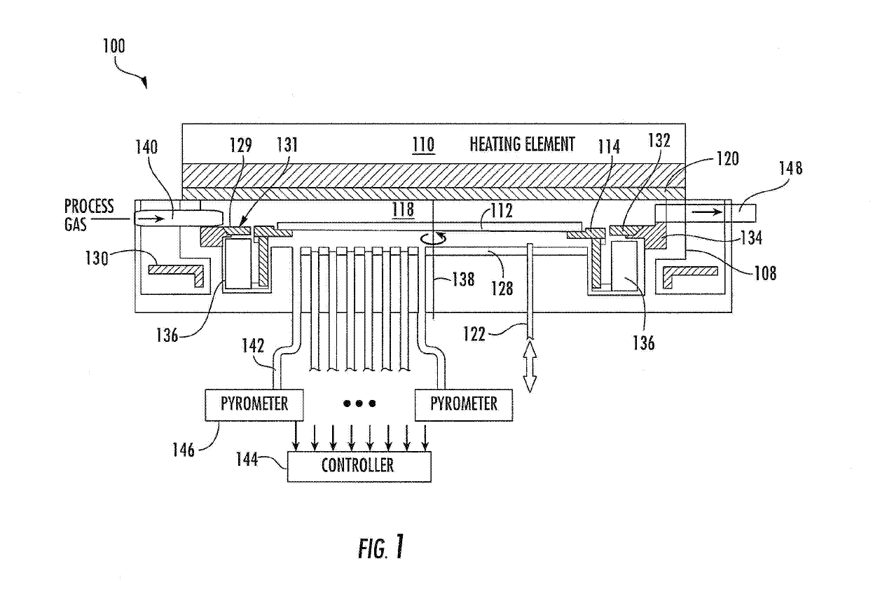

FIG. 1 is a cross sectional view of a process chamber 100 according to an implementation described herein. In one implementation, the process chamber 100 is a rapid thermal process chamber. In this implementation, the process chamber 100 is configured to quickly heat the substrate to volatilize materials from the surface of the substrate. In one example, the process chamber 100 may be a lamp based rapid thermal process chamber. Examples of suitable process chambers include the VULCAN™, RADOX™, and RADIANCE® tools available from Applied Materials, InC., Santa Clara, Calif. It is contemplated that suitably configured apparatus from other manufacturers may also be advantageously implemented according to the implementations described herein.

A substrate 112 to be processed in the chamber 100 is provided through the valve or access port (not shown) into the processing area 118 of the chamber 100. The substrate 112 is supported on its periphery by an annular substrate support 114 having an annular shelf contacting the corner of the substrate 112. The annular shelf may have a flat, curved, or sloping surface for supporting the substrate. Three lift pins 122 may be raised and lowered to support the back side of the substrate 112 when the substrate 112 is handled to and from a substrate transfer apparatus, such as a robot blade (not shown) which provides the substrate 112 into the chamber 100, and the substrate support 114. The process area 118 is defined on its upper side by a transparent quartz window 120 and on its lower side by the substrate 112, or by a substrate plane defined by the substrate support 114.

In order to heat the substrate 112, a radiant heating element 110 is positioned above the window 120 to direct radiant energy toward the substrate 112. In the chamber 100, the radiant heating element 110 may include a large number of high-intensity tungsten-halogen lamps positioned in respective reflective tubes arranged in a hexagonal close-packed array above the window 120. As provided herein, rapid thermal processing (RTP) refers to an apparatus of a process capable of uniformly heating a substrate at rates of about 50° C./sec and higher, for example at rates of about 100° C. to about 150° C./sec, and about 200° to about 400° C./sec. Typical ramp-down (cooling) rates in RTP chamber are in the range of about 80° C. to about 150° C./sec. Some processes performed in RTP chambers require variations in temperature across the substrate of less than a few degrees Celsius. Thus, an RTP chamber may include a lamp or other suitable heating system and heating system control capable of heating at a rate of up to about 100° C. to about 150° C./sec, and about 200° to about 400° C./sec.

However, other radiant heating apparatuses may be substituted to provide radiant heat energy to the chamber 100. Generally, the lamps involve resistive heating to quickly elevate the energy output of the radiant source. Examples of suitable lamps include incandescent and tungsten halogen incandescent lamps having an envelope of glass or silica surrounding a filament and flash lamps which comprise an envelope of glass or silica surrounding a gas, such as xenon and arc lamps that may comprise an envelope of glass, ceramic, or silica that may surround a gas or vapor. Such lamps generally provide radiant heat when the gas is energized. As provided herein, the term lamp is intended to include lamps having an envelope that surrounds a heat source. The “heat source” of a lamp refers to a material or element that can increase the temperature of the substrate, for example, a filament or gas that can be energized.

Certain implementations of the invention may also be applied to flash annealing. As used herein, flash annealing refers to annealing a substrate in under 5 seconds, such as less than 1 second, and in certain implementations, milliseconds.

The process chamber 100 may include a reflector 128 extending parallel to and facing the back side of the substrate 112. The reflector 128 reflects heat radiation emitted from the substrate 112 back to the substrate 112 to closely control a uniform temperature across the substrate 112. Dynamic control of the zoned heating is affected by one or a plurality of pyrometers 146 coupled through one or more optical light pipes 142 positioned to face the back side of the substrate 112 through apertures in the reflector 128. The one or plurality of pyrometers 146 measure the temperature across a radius of the stationary or rotating substrate 112. The light pipes 142 may be formed of various structures including sapphire, metal, and silica fiber. A computerized controller 144 receives the outputs of the pyrometers 146 and accordingly controls the voltages supplied to the heating element 110 to thereby dynamically control the radiant heating intensity and pattern during the processing.

The process chamber 100 includes a rotor 136. The rotor 136 allows the substrate 112 to be rotated about its center 138 by magnetically coupling the rotor 136 to a magnetic actuator 130 positioned outside the chamber 100. The rotor 136 comprises a magnetically permeable material such as an iron-containing material. A rotor cover 132 is removably disposed on a ring support 134 that is coupled to a chamber body 108. The rotor cover 132 is disposed over the rotor 136 to protect the rotor 136 from the extreme processing environment generated in the processing region 118. In one implementation, the ring support 134 is a lower liner and is made of quartz. The rotor cover 132 circumscribes the substrate support 114 while the substrate support 114 is in a processing position. The rotor cover 132 is formed from black quartz, but it is contemplated that the rotor cover 132 may be formed from other materials such as graphite coated with silicon carbide. The rotor cover 132 includes a segment 129 that is disposed adjacent a process gas inlet 140. The segment 129 has a top surface 131 and process gases flow across the top surface 131 from the process gas inlet 140 during operation. The top surface 131 may include features that increase the thermal conduction of the top surface 131. With an increased thermal conduction, the preheating of the process gases is improved, leading to improved process gas activation. The rotor cover 132 is described in detail below.

The heating element 110 may be adapted to provide thermal energy to the substrate and the rotor cover 132. The temperature of the rotor cover 132 during operation is about 100 degrees Celsius to about 200 degrees Celsius less than the temperature of the substrate 112. In one implementation, the substrate support 114 is heated to 1000 degrees Celsius and the rotor cover 132 is heated to 800 degrees Celsius. Typically the rotor cover 132 has a temperature between about 300 degrees Celsius and about 800 degrees Celsius during operation. The heated rotor cover 132 activates the process gases as the process gases flow into the process chamber 100 through the process gas inlet 140. The process gases exit the process chamber 100 through a process gas outlet 148. Thus, the process gases flow in a direction generally parallel to the upper surface of the substrate. Thermal decomposition of the process gases onto the substrate to form one or more layers on the substrate is facilitated by the heating element 110.

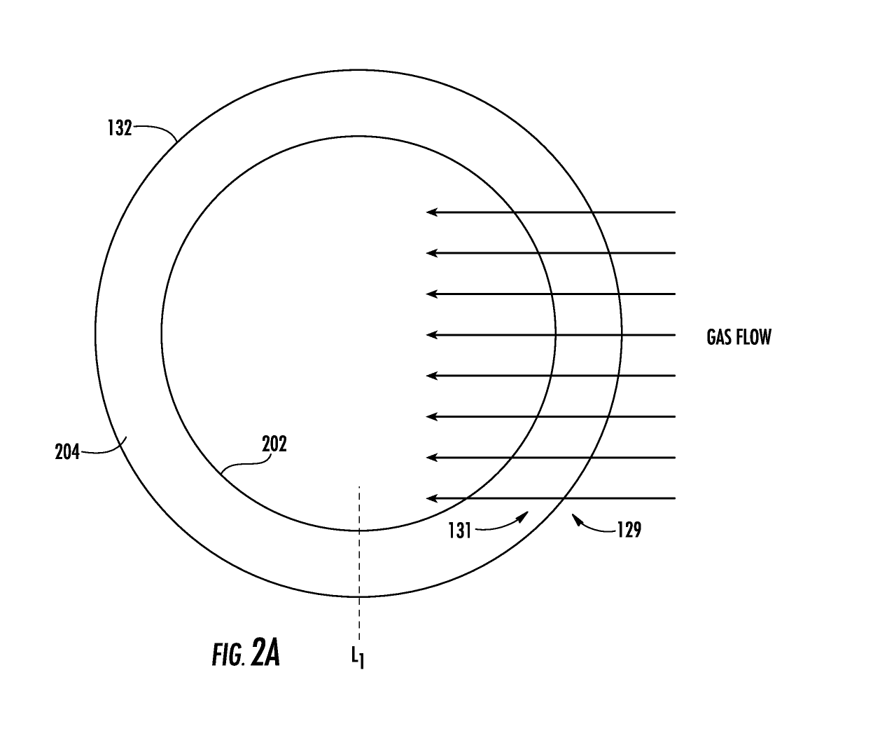

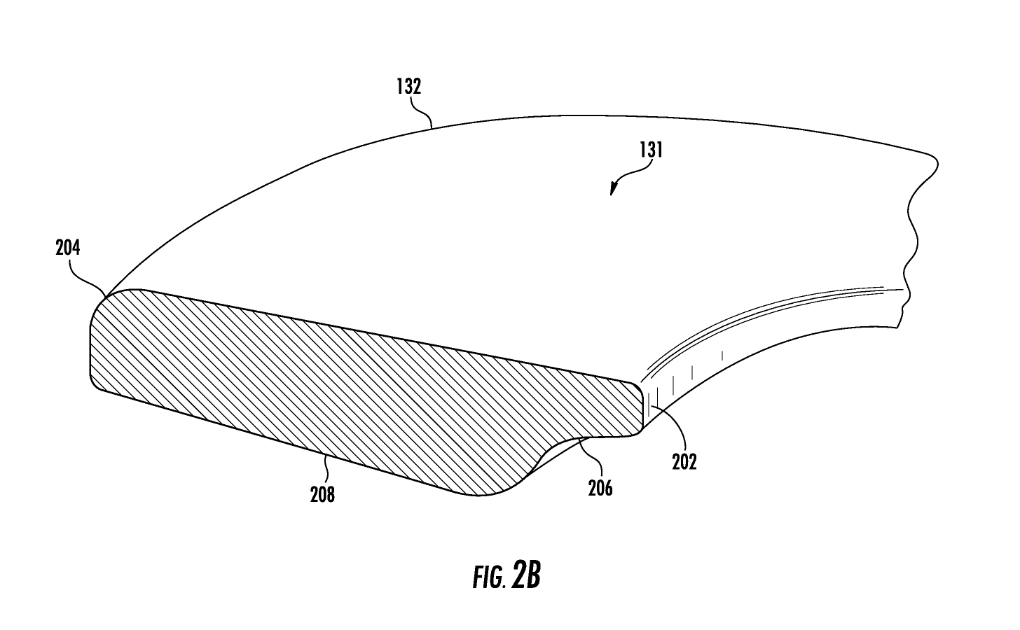

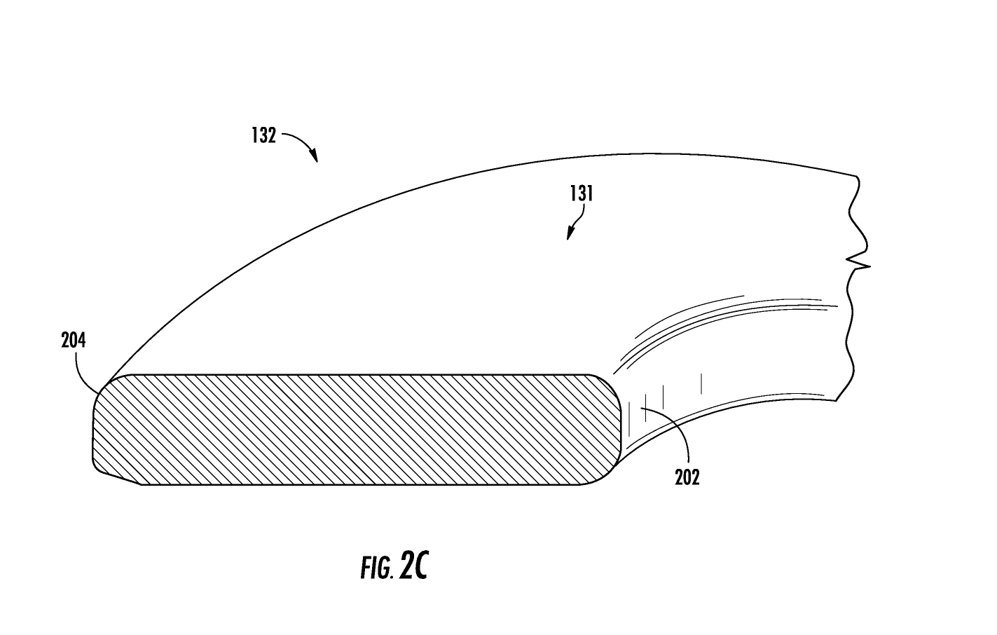

FIG. 2A shows a top view of the rotor cover 132 according to one implementation described herein. During operation, process gases flow across the rotor cover 132, as shown in FIG. 2A. In one implementation, the rotor cover 132 includes a cut or gap at “L1” to alleviate thermal expansion issues that may occur during processing. The rotor cover 132 is an annulus, or a substantially annular body in the case of a rotor cover with a gap, over the rotor 136 with an inner portion 202 extending toward the substrate support 114 and an outer portion 204 that impinges, or comes very near, the ring support 134. In one implementation, the rotor cover 132 is an annulus with a concave surface that extends between the inner edge 202 and the outer edge 204. In some implementations, the rotor cover 132 has an angled top surface 131 such that the height near the outer portion 204 is greater than the height of the inner portion 202, as seen in FIG. 2B and FIG. 3. In some cases, the outer portion 204 may be on the same plane or aligned with the gas inlet 140 while the inner portion 202 is at a height below the gas inlet 140. The top surface 131 may be concave. In another implementation, the height of the inner portion 202 is below the substrate 112. In one implementation, all the edges of the rotor cover are curved so that the rotor cover has no sharp edges. In one implementation the outer portion 204 of the rotor cover 132 may be curved.

The rotor cover 132 may include an inner lip 206 that projects radially inward from a body portion 209 of the rotor cover 132. The inner lip 206 may be disposed adjacent the substrate support 114. The inner lip 206 may be in the inner portion 202 of the rotor cover 132. A thickness of the inner lip 206 may be less than a thickness of the body portion 209. In one case, the top surface 131 extends radially inward further that the bottom surface 208. In such cases, the inner lip extends the top surface 131 to the inner portion 202, while the bottom portion 208 is connected to the inner portion 202 by a curved concave portion 207.

The inner portion 202 may allow air flow and cooling below the rotor cover 132 adjacent to the rotor 136. When the rotor cover 132 is installed in a processing chamber such as the chamber 100, the bottom surface 208 may be in contact with the ring support 134. In one implementation, the bottom surface 208 is opposite the top surface 131. The bottom surface 208 may include curved edges. In one implementation, the inner lip 206 extends radially inward farther than the bottom surface 208. In one implementation, the inner lip 206 is connected to the bottom surface 208 by the curved concave portion 207, which connects to the bottom surface 208 by a curved convex portion 205.

The inner portion 202 may be a vertical inner wall, as shown in FIG. 2B. In other implementations, the inner portion 202 may be a slanted or curved inner wall, which may incline toward the top surface 131 or toward the bottom surface 208. Thus, in some cases, the inner portion 202 is connected to the top surface 131 by an angled surface that slopes upward from the inner portion 202 to the top surface 131. In other cases, the inner portion 202 is connected to the bottom surface 208 by an angled surface that slopes downward from the inner portion 202 to the bottom surface 208.

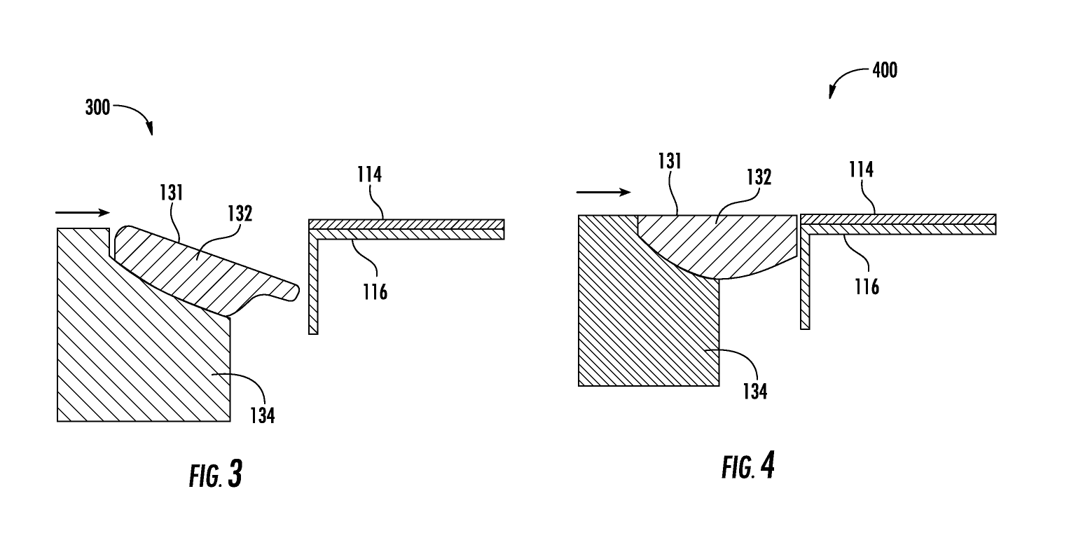

FIG. 2C shows a perspective view of a rotor cover 132 according to another implementation described herein. The rotor cover 132 has a substantially flat top surface 131, an inner portion 202, and an outer portion 204. The inner portion 202 and the outer portion 204 are both substantially vertical walls that connect to the top surface 131 by curved edges. The height of the rotor cover 132 near the outer portion 204 is substantially the same as the height near the inner portion 202, as seen in FIG. 2C and FIG. 4. In other words, the top surface 131 may be substantially horizontal from the inner portion 202 to the gas inlet 140. The substantially flat top surface 131 may help to preserve laminar flow across the rotor cover 132 from the gas inlet 140 to the substrate 112, and prevent gas and reactants from being diverted around the outside of the chamber. Additionally, the rotor cover 132 provides a greater surface area in contact with the gas as the gas flows across the top surface 131. With an increased surface area, preheating of the process gases is improved, leading to improved process gas activation. This implementation also changes the interaction between the rotor cover and other chamber parts. The flat bottom angle on the rotor cover provides limited contact with the chamber body and allows the rotor cover to maintain a high temperature, potentially increasing the reactive gas preheating. The reduced contact with the chamber body can also reduce particle generation from abrasion caused by thermal cycling. Furthermore, the cost of manufacturing the rotor cover 132 is substantially reduced as the post-machining process is performed faster with the streamlined design.

The rotor cover 132 comprises a material capable of withstanding the processing conditions of the thermal chamber without undergoing chemical change such as oxidation. As such, the material of the rotor cover 132 eliminates the conditioning trend or drift time associated with the chemical changes. In other words, the rotor cover 132 maintains substantially the same steady-state from the first use to the nth use which advantageously provides for a more uniform substrate processing. The rotor cover 132 may thus comprise an opaque quartz such as a silicon black quartz. The silicon black quartz may be made by growing and combining silicon into molten quartz, molding or casting the material, and then post-machining the cold ingot into the desired shape.

Advantageously, the opaque quartz provides for a lower recombination coefficient than other materials as reactants move across the rotor cover 132 towards the substrate 112. As reactants move across the rotor cover, an amount of reactant will be lost to the interaction with the material of the rotor cover. However, the opaque quartz rotor cover 132 advantageously resists interaction with the process gases and provides for a larger amount of reactants to reach the substrate 112. In another implementation, the rotor cover 132 is an encapsulated ceramic material or encapsulated stainless steel. The encapsulating material may be quartz such that the rotor cover 132 is an opaque material with quartz. During processing, particle contamination can occur due to the interaction of the rotor cover 132 with the ring support 134 as the rotor cover expands and contracts while heating in cooling during processing. The black quartz material of the rotor cover 132 advantageously has a low coefficient of thermal expansion (CTE) reducing interaction with the ring support 134 and ultimately reducing the particle contamination on the substrate 112.

FIG. 3 shows a cross sectional view of a rotor cover 132 within a chamber 300 according to one implementation described herein. The rotor cover 132 is disposed on the ring support 134. The bottom surface 208 is in contact with the ring support 134. The top surface 131 is angled downward. The outer portion of the rotor cover 132 adjacent the gas inlet 140 has a greater height than the inner portion of the rotor cover 132 which is adjacent the substrate support 114.

FIG. 4 shows a cross sectional view of a rotor cover 132 within a chamber 400 according to one implementation described herein. The rotor cover 132 is disposed on the ring support 134. The bottom surface 208 is in contact with the ring support 134. The rotor cover 132 has a substantially flat top surface 131. The height near the outer portion 204 is substantially the same as the height of the inner portion 202, as seen in FIG. 2C and FIG. 4. In other words, the outer portion 204 may be on the same plane or aligned with the inner portion 202 as well as the gas inlet 140. The substantially flat top surface 131 advantageously preserves the laminar flow across from the gas inlet 140 as it flows towards the substrate 112. Additionally, the rotor cover 132 provides a greater surface area coming in contact with the gas as the gas flows across the top surface 131. With an increased surface area, the preheating process of the process gases is improved, leading to improved process gas activation. Furthermore, the cost of manufacturing the rotor cover 132 is substantially reduced as the post-machining process is performed faster with the streamlined design.

In summary, a processing apparatus having a rotor cover is disclosed. The rotor cover may provide for better heating of the process gases. The rotor cover may provide for more consistent processing as the material of the rotor cover substantially eliminates the conditioning trend associated with chemical processes such as oxidation. The material of the preheat has a low recombination coefficient such that more of the process gases reaches the substrate, thus providing for more efficient and uniform processing. The interaction between the process gases and the rotor cover is substantially reduced preserving laminar flow as the gas flows towards the substrate. Furthermore, the rotor cover material has a low CTE reducing particle contamination due to excessive expansion during processing.

While the foregoing is directed to implementations of the present invention, other and further implementations of the invention may be devised without departing from the basic scope thereof, and the scope thereof is determined by the claims that follow.

1. A cover for a thermal treatment chamber, comprising:
an opaque quartz annulus comprising:
an inner edge having a first thickness; and
an outer edge having a second thickness greater than the first thickness.

2. The cover of claim 1, wherein the opaque quartz annulus is made of silicon black quartz.

3. The cover of claim 1, wherein the opaque quartz annulus further has a concave surface between the inner edge and the outer edge.

4. The cover of claim 3, wherein the annulus further comprises an inner lip that extends radially inward to the inner edge from the concave surface.

5. The cover of claim 3, wherein the concave surface is between the inner lip and a bottom of the annulus.

6. The cover of claim 1, wherein the annulus has a top surface, and wherein the top surface of the annulus is concave.

7. An apparatus for processing a substrate, comprising:
a chamber body having a side wall and a bottom wall defining an interior processing region;
a substrate support disposed in the interior processing region of the chamber body;
a ring support extending inwardly from the side wall; and
a cover disposed on the ring support, wherein the cover comprises an opaque quartz material.

8. The apparatus of claim 7, wherein the opaque quartz material is silicon black quartz.

9. The apparatus of claim 7, wherein the cover has an annular body having a third thickness and an inner lip having a fourth thickness less than the third thickness, wherein the inner lip extends radially inward from the annular body.

10. The apparatus of claim 7, wherein the cover has an outer portion and an inner portion, and wherein the outer portion has a thickness greater than a thickness of the inner portion.

11. The apparatus of claim 7, wherein a top of the inner portion is on the same plane as a top of the substrate support.

12. The apparatus of claim 11, wherein a top of the outer portion is on the same plane as a top of the substrate support.

13. The apparatus of claim 7, further comprising a gap between the cover and the substrate support.

14. An apparatus for processing a substrate, comprising:
a chamber body having a side wall and a bottom wall defining an interior processing region;
a substrate support disposed in the interior processing region of the chamber body;
a ring support extending inwardly from the side wall; and
a cover disposed on the ring support, wherein the cover comprises an outer portion and an inner portion, wherein a top of the outer portion is on the same plane as a top of the substrate support, and wherein a top of the inner portion is on a different plane than the top of the substrate support.

15. The apparatus of claim 14, wherein the outer portion has a thickness substantially the same as the inner portion.

16. The apparatus of claim 14, wherein the cover is an annulus.

17. The apparatus of claim 16, wherein the annulus is an opaque quartz material.

18. The apparatus of claim 17, wherein the opaque quartz material is silicon black quartz.

19. The apparatus of claim 14, wherein the cover is an opaque quartz material.

20. The apparatus of claim 19, wherein the opaque quartz material is silicon black quartz.
